(19) United States
(12) Patent Application Publication
(10) Pub. No.: US 2016/0193866 A1
(43) Pub. Date: Jul. 7, 2016

(54) METHOD FOR PRODUCING A SURFACE STRUCTURE ON A PRESSING TOOL BY APPLYING METAL COATINGS

(71) Applicant: HUECK RHEINISCHE GMBH, Viersen (DE)

(72) Inventors: Wolfgang STOFFEL, Kempen (DE); Martin MARXEN, Viersen (DE)

(73) Assignee: HUECK Rheinische GmbH, Viersen (DE)

(21) Appl. No.: 14/916,432

(22) PCT Filed: Jul. 23, 2014
(86) PCT No.: PCT/EP2014/002010

§ 371 Date: Mar. 3, 2016

(30) Foreign Application Priority Data
Sep. 13, 2013 (EP) 13004467.0

(51) Int. Cl. B44C 3/02; B44F 9/02; B30B 3/00; B29C 59/04; B30B 15/06; C23C 16/04; B29C 59/00; B29C 59/02; B44B 5/02; B30B 5/04

(52) U.S. Cl. CPC B44C 3/025; B44B 5/026; B44F 9/02; B30B 3/005; B30B 5/04; B30B 15/062; C23C 16/04; B29C 59/005; B29C 59/022; B29C 59/04

(57) ABSTRACT

The invention relates to a method for producing a surface structure on a pressing tool, in particular a pressing plate (1), endless belt or embossing roller. According to the invention, in order to avoid a lengthy etching process, the surface structure is produced by means of metal layers lying one over the other. For this purpose, at least a one-time application of a mask is performed in order to cover partial regions and at least a one-time application of a metal layer to the non-covered regions (5, 6) is performed in order to construct a surface structure composed of elevations. The two individual method steps are repeated until the desired structure depth has been reached. By means of a final treatment method, the surface can be rounded or provided with a hard chromium layer (7), for example.

The invention relates to a method for producing a surface structure on a pressing tool, in particular a pressing plate, endless belt or embossing roller.

Embossing tools in the form of pressing plates, endless belts or embossing rollers are widely used in the wood processing industry. This might be for producing furniture but also for producing panels for interior decor where the panels may be used for cladding walls and ceilings and for flooring. The embossing tools are used to emboss the visible surface of the material plates in order to produce a desired motif, preferably a realistic imitation of a natural surface structure. The design of die surface is freely selectable so that graphic structures or patterns may also be used. In order to produce the material plates, resin-impregnated paper sheets are placed on a substrate layer which might be HDF, MDF, USB, chipboard or plywood boards. The paper sheets comprise at least a decor paper and an overlay paper disposed above the decor paper. The number of paper layers is freely selectable and depends on the intended purpose, so that several overlay papers may be laid on the decorative layer or several underlay papers may be laid underneath the decorative layer, for example.

To prevent warping of the material plates, both sides are preferably faced with more or less the same number of overlay and underlay papers which are pressed onto the substrate layer.

In terms of resin, thermosetting resins are used, for example in the form of melamine, phenolic, amino or melamine/urea resins, which allow the paper layer to appear transparent so that only the print of the decorative layer or a colored paper layer is clearly visible once the product is finished.

In pressing machines, for example in single daylight presses, the material plates are heated and pressed onto the papers. The pressing time and temperature determine the degree of crosslinking of the resins and their surface quality. Once the pressing time has elapsed, the resin has reached the desired degree of crosslinking and is in a solid phase. During this process, the surface structure of the embossing tool is imparted to the resin surface.

In addition, the paper layers impregnated with resin, which might be soda kraft and alpha cellulose papers for example, are pressed with one another as an HPL layer. Individual paper layers can be printed or may be of a single color and folded, and because the paper layers are transparent after having been impregnated with the resins, the decorative pattern and color tones are clearly visible. The designs, like the types of material plates, are many and varied because of the decor papers and may be imitations of stone, leather, fabric or wood, for example, and because of the pressing tools used they may be provided with an in-register structure. When producing laminate flooring, decorative structures are embossed by means of a structure on the pressing plate extending in-register which makes the imitation wood look particularly realistic. The embossed structure is superimposed on the decor papers used, i.e. they are embossed in-register so that the recesses follow the contour of the motif, for example, thus enhancing the natural look of the material plates or HPL layer. The HPL layer can be joined to a substrate layer, for example by means of an adhesive.

To produce the surface structure, a structured metal pressing plate or endless belt is used as an embossing tool, preferably a steel plate. If embossing rollers are used, they will likewise have a structure on the outer surface or may be faced with an embossing plate. In order to improve the wear resistance and release properties of the metal surface, the embossing tools are additionally provided with a coating. The coating might be a chromium coating, for example.

In the past, pressing tools were produced by means of a screen printing process or alternatively by applying a photo-coating which is then exposed to illumination so that once the photo-coating has developed, the pressing plates or endless belts can be subjected to a cleaning process after which only the parts of the photo-coating that will form the mask for the subsequent etching process are left intact. Alternatively, another option is to apply the requisite mask using a digitized printing process in order to prepare the pre-treated pressing tool for an etching process. In this case, the data of the decor papers can also be used for exactly applying the mask so that particularly effective in-register embossing of the final material plate can be obtained. In the latter case, the mask is applied by means of a print head, and a print head is moved along an X and Y axis or, in the case of a stationary print head, the work table with the pressing tool lying on it is moved underneath the print head.

Another alternative is the option whereby direct structuring is applied by means of a water jet process or using laser technology. In this case, there is no need to apply a mask beforehand to produce surface structuring.

Irrespective of which form of surface structuring was produced on the pressing tools, they have to be subjected to several cleaning processes and can additionally be coated with a layer of nickel, brass or copper so that the quality of the surface can then be improved by other metal coatings. It is preferable to use a chromium coating for this purpose. The metal coatings impart a desired degree of gloss to the surface and the requisite hardness. Once the material plates to be processed have been pressed by means of the pressing tools, the degree of gloss imparts different shades and color play to the pressed structure.

All of the processing techniques described above require complex processing of the pressing tools, which is ultimately reflected in the production costs. The multiple processes of etching the pressing tools in particular demand lengthy processing times.

For the reasons outlined above, the underlying objective of this invention is to propose a new type of method whereby etching processes can be almost entirely dispensed with.

To achieve the objective relating to the method, the following steps are proposed as a means of producing a structured surface on a pressing tool with an originally smooth surface:
an at least one-time application of a mask is performed in order to cover partial regions and
at least a one-time application of a metal layer to the non-covered regions is performed in order to construct a surface structure composed of elevations.

Other advantageous embodiments of the method are defined in the dependent claims.

In order to produce the surface structure using the proposed method, etching is dispensed with. Instead, at least one mask is applied once to a prepared pressing tool, which initially is just a steel plate, in order to cover partial regions of the surface. Having produced the mask, a first metal layer is applied to the non-covered regions by at least a one-off application of a metal layer in order to construct a surface structure composed of elevations. Just by applying a first metal coating, a slight surface structuring is created which, by repeating the individual method steps several times, i.e. applying a mask again and then applying another metal layer, leads to a layered structure of the elevations. The number of layers to be applied for this purpose is defined solely by the depth of the surface structure to be obtained. If necessary, a plurality of individual layers can be applied one on top of the other, in which case in order to apply a new metal layer, a new mask most be applied beforehand. Due to the application of several metal layers one on top of the other in this manner, a sort of pyramid-shaped structure is created and in the simplest case, there is no need to remove the previously applied mask. Instead, another mask can be applied directly on top of the existing mask and other partial regions of the metal layer. As soon as the number of applied layers corresponds to the subsequently desired structure depth, all of the masks can be removed in one operation. Alternatively, it is also naturally possible for the previous mask to be removed before applying a new mask.

The advantage of such an approach is that any etching of the pressing tools can be completely dispensed with using theses method steps. The surface structure is obtained merely by applying additional metal layers disposed one on top of the other. To obtain the metal layer, a nickel, copper or chromium layer may be applied, for example. Having completed the surface structuring, a hard chromium layer can be applied in addition.

In order to apply the mask, the invention proposes using a digital printing process, in which case it is preferable to use a UV lacquer which is irradiated by means of a UV source after application so that it cures. The mask is applied on a work table with the aid of a print head which is disposed so that it can be moved in a plane defined by the X and Y components. Alternatively, another option is to use a stationary print head and move the work table together with the pressing tool in the X and Y direction.

Based on another embodiment of the method for obtaining the surface structuring, the successive masks are applied more or less to the same partial regions. The first mask applied more or less determines the region that will form the subsequent recesses whilst the surface structure will be created in the non-covered regions by the successive application of several metal layers. For this reason, the individual masks will lie either one on top of the other if the older masks were not removed beforehand, or the same regions and peripheral regions of the metal coating will be covered by the masks to enable the other coating operations to be run in only the raised regions. The metal layers are applied one on top of the other to the degree that an elevated structure is created perpendicular to the surface of the pressing tool layer by layer. In order to obtain the pyramid-shaped structure, the subsequently applied masks differ due to a coating area which becomes ever wider and continuously increases until ultimately only the narrow regions of the elevations are left for a final metal layer to be produced.

Based on another embodiment of the invention, in order to improve adhesion of the masks to be applied or prepare for another pre-treatment of the pressing tools which might be necessary, the surface of the pressing tool is galvanically, chemically or mechanically pre-treated prior to applying the first mask in order to roughen the metal surface.

Based on another embodiment of the invention, after the individual metal layers have been applied one on top of the other in a pyramid-shaped arrangement, the surface of the pressing tool is subjected to a galvanic, chemical or mechanical treatment after applying the last metal layer. An etching process might be used for this purpose in order to round the metal layers applied layer by layer. Furthermore, other treatment steps may be run in order to finish the pressing tool, in which case the next surface treatment might be electro-polishing or mechanical polishing, for example, in order to obtain a specific degree of gloss. Alternatively, another option is to obtain the degree of gloss by etching or matt etching in a subsequent surface treatment. Using this approach, the degree of gloss is usually adjusted so as to be uniform across the entire surface of the pressing tool.

In order to produce a different degree of gloss, based on another embodiment of the invention, a full-surface and/or partial degree of gloss is produced during a subsequent surface treatment and the degree of gloss is adjusted by applying a metal coating, by a chemical process or by a mechanical process. Alternatively in this case, there is also the option of adjusting the degree of gloss by etching or matt etching. If essentially comes down to the application for which the material plates are intended and if the material plates are being produced for the furniture industry, they will be subjected to a chemical or a mechanical treatment process to adjust the degree of gloss followed by hard chrome plating. If the material plates are to be used to produce flooring panels, other metal coatings may be applied in order to adjust the degree of gloss, and a first degree of gloss can be obtained in the region of the elevations of the pressing tools during the surface structuring process already.

Based on another embodiment of the invention, a full-surface and/or partial degree of gloss is created as the next surface treatment. In this respect, applying partial hard chromium layers offers the possibility of varying the degree of gloss and the recesses may appear to have a different degree of gloss from the elevations, for example, and this is achieved initially as a negative impression on the pressing tool and then on the surface of the material plate after pressing. Which regions will have a low degree of gloss and which will have a high degree of gloss will depend on the requirements of the client ordering the end product. Based on the method steps outlined above, every design option is basically possible when it comes to the degree of gloss.

The key thinking behind this method proposed by the invention is to dispense with etching as a means of producing the surface structure and to apply a partial coating in the form of a metal layer after applying individual masks, and this can be repeated several times until the desired surface structure has been created layer by layer.

Another objective of the invention is to propose a device for implementing the method.

The device proposed by the invention comprises a supporting device for the pressing tools for applying a surface treatment, and digitized data of an impression of the surface structure is used to control application of the mask, and the print head is moved in the direction of the X and Y co-ordinates within a spanned plane or, in the case of a stationary print head, the supporting device can be moved in the X and Y direction and at least one mask can be applied to cover at least partial regions in readiness for applying at least a first metal coating to the non-covered regions in an electroplating device. This process can be implemented at least once but is preferably repeated several times so that a surface structure is created on the pressing tools layer by layer. Accordingly, additional layers are preferably applied to the layers already applied, enabling a surface structure to be created without the need for an etching process. The mask needed for this purpose is applied to the surface of what will ultimately be the pressing tool, preferably a steel plate, in readiness for depositing the first metal layer in an electroplating device, preferably a galvanic bath.

Once removed from the galvanic bath, the surface is cleaned and the first mask can be removed. A second mask can then be applied and the metal coating process repeated. Both processes can be repeated several times, one after the other, in order to create the surface structuring layer by layer. As an alternative to removing the mask each time, however, this method also offers the possibility of leaving the masks on the surface because every additional mask that is applied has a wider coating area than the previous mask. This being the case, once the surface structuring has been completed, all of the masks can be removed in one operation or several of the masks applied can be removed in one step. This is made possible because the way the mask is handled and the multiple applications mean that there is no need to worry about the mask flaking.

The invention further relates to the use of an embossing tool, namely in the form of a pressing plate, endless belt or cylindrical embossing roller, produced as specified in one of the method claims and used for pressing and/or embossing material plates with a naturalistic structured surface up to a depth of 500 pm, and the surface structuring is created by applying a metal coat layer by layer.

The invention also relates to a material plate produced using a pressing tool according to one of the method steps, having a surface structure applied layer by layer.

The invention will be described in more detail with reference to the appended drawings.

Of these

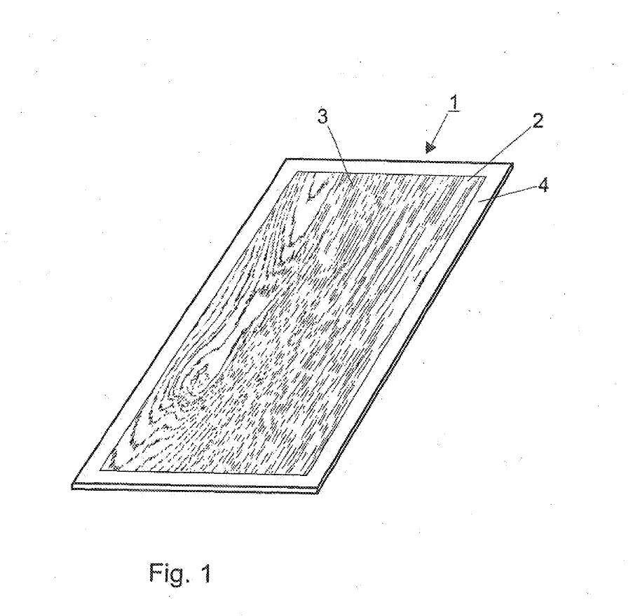

FIG. 1 is a perspective view of a pressing plate with surface structuring,

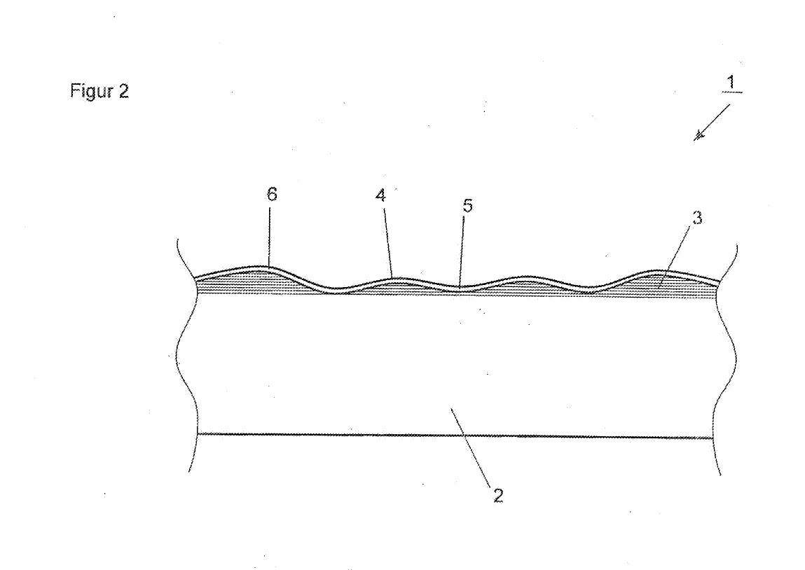

FIG. 2 is a very much enlarged cross-sectional view of the pressing plate illustrated in FIG. 1 with a surface structure applied layer by layer and

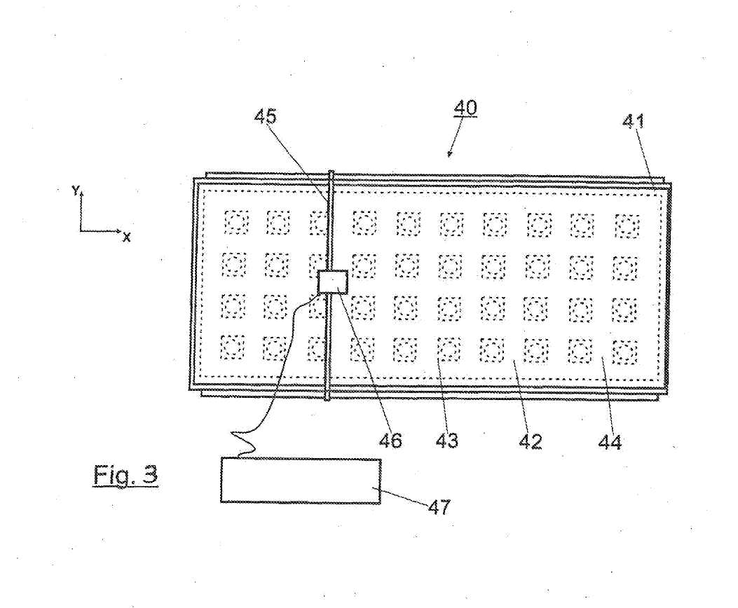

FIG. 3 is a plan view of a device for implementing the method proposed by the invention.

FIG. 1 is a perspective view illustrating a pressing plate 1 with surface structuring, which may be a plate of steel or brass. Simulated on the surface 2 of the pressing plate 1 is a wood grain 3, which was produced by repeatedly applying a mask and then a metal coating. In principle, it is possible to produce any type of surface structuring, for example simulating a natural stone surface of a geographic pattern or alternatively wood structures.

A peripheral edge 4 is used for retaining and securing purposes in a hydraulic single or multi-daylight press, although this is not illustrated.

FIG. 2 is a view of the pressing plate 1 in cross-section on a much larger scale, from which it may be seen that the pressing plate 1 comprises a base body 8 on which individual layers 9 of metal are disposed one on top of the other. The layered structure is created by applying a mask to partial regions of the base body 8 and then a metal coating, which can be repeated several times. To this end, it is necessary to apply a new mask each time and then a new metal coating until the desired structure depth formed by the elevated regions 5 and the deeper lying regions 6 is obtained. Seen in plan view, the regions 5 and 6 create a structure such as that illustrated in FIG. 1, for example, imitating a wood decoration. The method proposed by the invention dispenses with the etching process as a means of creating the surface structure and instead, individual metal layers are applied after each application of a mask. The depth profile can be set on the basis of the number of metal layers 3 applied. As a finish, a hard chromium layer 10 is applied on top of the metal layers 3, which may extend across the entire surface of the pressing plate 1, for example. Alternatively, another option is to apply the hard chromium layer 10 solely in the area of the deeper lying regions 6, whilst the elevated regions 5 are coated with a different chromium coating having a different degree of gloss, for example. This feature enables material plates to be produced with the pressing plates 1 that not only have structuring but also a degree of gloss.

FIG. 3 is a plan view illustrating a device 40 for implementing the method proposed by the invention with a print head 46. The device 40 comprises a supporting table 41 with a flat work surface 42. Disposed within the work surface 42 are recesses 43 which are connected to a vacuum pump so that a pressing plate 1 placed on the work surface 42 can be aspirated and thus held fixed for the subsequent processing operations. A print head 46 can be moved in the direction of the Y co-ordinates by means of a cross-member 45. The cross-member 45 can also be moved in the direction of the X co-ordinates so that the print head 46 is able to reach every point of the surface of the pressing plate 1. Instead of moving the print head 46, a stationary print head 46 may also be used, in which case the work surface 42 with the pressing plate 1 lying on it is moved in the X and Y directions.

A control unit 47 controls the movements of the cross-member 45 and print head 46 and is activated on the basis of digitized data representing an impression of a 3D structure. Once the mask is finished, the pressing plate 46 can be provided with a metal coat.

### LIST OF REFERENCE NUMBERS

1. Pressing plate
2. Surface
3. Wood grain
4. Edge
5. Region
6. Region
7. Hard chromium layer
8. Base body
9. Layer
10. Hard chrome plating
40. Device
41. Supporting table
42. Work surface
43. Recess
45. Cross-member
46. Print head
47. Control unit

1-15. (canceled)

16: A method for producing a surface structure on a pressing tool, in particular a pressing plate (1), endless belt or embossing roller, comprising at least the steps: at least a one-time application of a mask is performed in order to cover partial regions and at least a one-time application of a metal layer to the non-covered regions (5, 6) is performed in order to construct a surface structure composed of elevations, and the mask and metal layer are applied several times, layer by layer, and wherein etching of the pressing tools is totally dispensed with during these method steps.

17: The method according to claim 16, wherein the mask is applied by means of a digital printing process.

18: The method according to claim 17, wherein UV lacquer is used which is irradiated by means of a UV source after application in order to cure it.

19: The method according to claim 16, wherein the successive masks are applied to more or less the same partial regions (5, 6).

20: The method according to claim 16, wherein the metal layers are applied one on top of the other, thereby constructing an elevated structure perpendicular to the surface of the pressing tool layer by layer.

21: The method according to claim 16, wherein the successive in-register masks have a coating width which continuously increases.

22: The method according to claim 16, wherein the successive metal layers are disposed one on top of the other in a pyramid shape.

23: The method according to claim 16, wherein the surface of the pressing tool is galvanically, chemically or mechanically pre-treated prior to applying the first mask.

24: The method according to claim 16, wherein the surface of the pressing tool is subjected to a galvanic, chemical or mechanical treatment after applying the last metal layer.

25: The method according to claim 16, wherein a subsequent surface treatment is carried out by electro-polishing or mechanical polishing or a subsequent surface treatment is carried out by etching or matt etching.

26: The method according to claim 16, wherein a full-surface and/or partial degree of gloss is produced as a subsequent surface treatment and the degree of gloss is adjusted by applying a metal coating, by a chemical process or by a mechanical process.

27: The method according to claim 16, wherein a complete and/or partial hard chrome plating (10) is applied to the surface structure as a subsequent surface treatment.

28: A device for implementing the method according to claim 16, comprising a supporting device for the pressing tools for applying a surface treatment, wherein it is used to implement the method, and digitized data of an impression of the surface structure is used to control application of the mask, and the print head (46) is moved in the direction of the X and Y co-ordinates within a spanned plane or, in the case of a stationary print head (46), the supporting device can be moved in the X and Y directions, and the print head is configured to apply at least one mask which covers at least partial regions (5, 6) in order to apply at least a first metal coating to the non-covered regions (5, 6) in an electroplating device, and the device is configured to effect at least a one-time repetition of applying the mask and coating so that the surface structure is created in a layer by layer arrangement.

29: A pressing tool, produced by the method according to claim 16.

30: A material plate produced using a pressing tool according to claim 29 having a surface structure applied layer by layer.
